(19) United States
(12) Patent Application Publication
(10) Pub. No.: US 2025/0147347 A1
(43) Pub. Date: May 8, 2025

(54) METHOD FOR INSPECTING REFLECTING DEVICE

(71) Applicant: Japan Display Inc., Tokyo (JP)

(72) Inventors: Daiichi SUZUKI, Tokyo (JP); Shinichiro OKA, Tokyo (JP); Mitsutaka OKITA, Tokyo (JP)

(73) Assignee: Japan Display Inc., Tokyo (JP)

(21) Appl. No.: 19/016,275

(22) Filed: Jan. 10, 2025

Related U.S. Application Data
(63) Continuation of application No. PCT/JP2023/019428, filed on May 25, 2023.

(30) Foreign Application Priority Data
Aug. 1, 2022 (JP) 2022-122666

(51) Int. Cl. G02F 1/13; G01R 29/08

(52) U.S. Cl. CPC G02F 1/1309; G01R 29/0871; G02F 2203/02

(57) ABSTRACT

A method for inspecting a reflecting device, which has a plurality of reflecting elements arrayed in a matrix, each of the plurality of reflecting elements comprises a patch electrode, a common electrode on a back side of the patch electrode, and a liquid crystal layer between the patch electrode and the common electrode, a first voltage V1 is applied between one of the plurality of patch electrodes and the common electrode, and whether the reflecting element is good or bad is determined based on changes in a frame region that appears around a periphery of one of the plurality of patch electrodes in a top view when a voltage is applied between one of the plurality of patch electrodes and the common electrode.

### CROSS-REFERENCE TO RELATED APPLICATIONS

This application is a Continuation of International Patent Application No. PCT/JP2023/019428, filed on May 25, 2023, which claims the benefit of priority to Japanese Patent Application No. 2022-122666, filed on Aug. 1, 2022, the entire contents of which are incorporated herein by reference.

### FIELD

The present invention relates to a method for inspecting a reflecting device.

### BACKGROUND

A phased array antenna device controls the directivity of an antenna in a fixed state by adjusting the amplitude and phase of a high-frequency signal applied to each of a plurality of antenna elements arranged in a plane. A phased array antenna device requires a phase shifter. The phased array antenna device using a phase shifter that utilizes a change in dielectric constant due to the orientation state of a liquid crystal is disclosed (for example, refer to Japanese laid-open patent publication No. H11-103201 and Japanese laid-open patent publication No. 2019-530387).

For a reflecting device that uses liquid crystals, it is desirable to have a method to determine if the reflecting element is good or bad by observing a reflecting element that does not control the desired radio waves.

Furthermore, since a reflecting device often uses a light-shielding metal for a patch electrode, unlike a display device that uses a transparent electrode for a pixel electrode, it is desirable to expand the area where the interior of the reflecting device can be directly observed in a nondestructive manner.

### SUMMARY

In a method for inspecting a reflecting device in an embodiment according to the present invention, the reflecting device has a plurality of reflecting elements arrayed in a matrix, each of the plurality of reflecting elements comprising a patch electrode, a common electrode on a back side of the patch electrode, and a liquid crystal layer between the patch electrode and the common electrode, a first voltage V1 is applied between one of the plurality of patch electrodes and the common electrode, and a determination is made whether the reflecting element is good or bad based on changes in a frame region that appears around a periphery of one of the plurality of patch electrodes in a top view when a voltage is applied between one of the plurality of patch electrodes and the common electrode.

### BRIEF DESCRIPTION OF DRAWINGS

FIG. 1A is a plan view of a reflecting element utilized in a reflecting device according to an embodiment of the present invention.

FIG. 1B shows a cross-sectional view of a reflecting element utilized in a reflecting device according to an embodiment of the present invention.

FIG. 2A is a diagram showing a state in which no voltage is applied between a patch electrode and a common electrode when a reflecting element utilized in a reflecting device according to an embodiment of the present invention operates.

FIG. 2B is a diagram showing a state in which a voltage is applied between a patch electrode and a common electrode when a reflecting element utilized in a reflecting device according to an embodiment of the present invention operates.

FIG. 3 is a diagram showing a structure of a reflecting device according to an embodiment of the present invention.

FIG. 4 is a schematic diagram showing a change in the traveling direction of a reflected wave by a reflecting device according to an embodiment of the present invention.

FIG. 5 shows a configuration of a reflecting device according to an embodiment of the present invention.

FIG. 6 shows a cross-sectional view of a reflecting element utilized in a reflecting device according to an embodiment of the present invention.

FIG. 7 is a plan view of an inspection method for a reflecting element utilized in a reflecting device according to an embodiment of the present invention.

FIG. 8A is a plan view of an inspection method for a reflecting element utilized in a reflecting device according to an embodiment of the present invention.

FIG. 8B is a plan view of an inspection method for a reflecting element utilized in a reflecting device according to an embodiment of the present invention.

FIG. 8C is a plan view of an inspection method for a reflecting element utilized in a reflecting device according to an embodiment of the present invention.

FIG. 9A is a plan view of an inspection method for a reflecting element utilized in a reflecting device according to an embodiment of the present invention.

FIG. 9B is a plan view of an inspection method for a reflecting element utilized in a reflecting device according to an embodiment of the present invention.

FIG. 9C is a plan view of an inspection method for a reflecting element utilized in a reflecting device according to an embodiment of the present invention.

FIG. 10A is a plan view of an inspection method for a reflecting element utilized in a reflecting device according to an embodiment of the present invention.

FIG. 10B is a plan view of an inspection method for a reflecting element utilized in a reflecting device according to an embodiment of the present invention.

FIG. 10C is a plan view of an inspection method for a reflecting element utilized in a reflecting device according to an embodiment of the present invention.

FIG. 11A is a plan view of an inspection method for a reflecting element utilized in a reflecting device according to an embodiment of the present invention.

FIG. 11B is a plan view of an inspection method for a reflecting element utilized in a reflecting device according to an embodiment of the present invention.

FIG. 11C is a plan view of an inspection method for a reflecting element utilized in a reflecting device according to an embodiment of the present invention.

FIG. 12A is a plan view of an inspection method for a reflecting element utilized in a reflecting device according to an embodiment of the present invention.

FIG. 12B is a plan view of an inspection method for a reflecting element utilized in a reflecting device according to an embodiment of the present invention.

FIG. 12C is a plan view of an inspection method for a reflecting element utilized in a reflecting device according to an embodiment of the present invention.

FIG. 13A is a plan view of an inspection method for a reflecting element utilized in a reflecting device according to an embodiment of the present invention.

FIG. 13B is a plan view of an inspection method for a reflecting element utilized in a reflecting device according to an embodiment of the present invention.

FIG. 13C is a plan view of an inspection method for a reflecting element utilized in a reflecting device according to an embodiment of the present invention.

FIG. 14A is a plan view of an inspection method for a reflecting element utilized in a reflecting device according to an embodiment of the present invention.

FIG. 14B is a plan view of an inspection method for a reflecting element utilized in a reflecting device according to an embodiment of the present invention.

FIG. 14C is a plan view of an inspection method for a reflecting element utilized in a reflecting device according to an embodiment of the present invention.

FIG. 15A is a cross-sectional view of an inspection method for a reflecting element utilized in a reflecting device according to an embodiment of the present invention.

FIG. 15B is a cross-sectional view of an inspection method for a reflecting element utilized in a reflecting device according to an embodiment of the present invention.

FIG. 15C is a cross-sectional view of an inspection method for a reflecting element utilized in a reflecting device according to an embodiment of the present invention.

FIG. 16 is a plan view of an inspection method for a reflecting element utilized in a reflecting device according to an embodiment of the present invention.

### DESCRIPTION OF EMBODIMENTS

Hereinafter, embodiments of the present invention are described with reference to the drawings. However, the present invention can be implemented in many different aspects, and should not be construed as being limited to the description of the following embodiments. For the sake of clarifying the explanation, the drawings may be expressed schematically with respect to the width, thickness, shape, and the like of each part compared to the actual aspect, but the drawings are only an example and do not limit the interpretation of the present invention. In this specification and each drawing, elements similar to those described previously with respect to previous drawings may be given the same reference sign (or a number followed by a, b, etc.) and a detailed description may be omitted as appropriate. The terms “first” and “second” appended to each element are a convenience sign used to distinguish them and have no further meaning except as otherwise explained.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

### 1. Reflecting Element

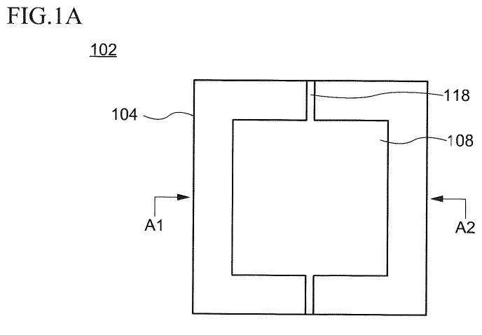

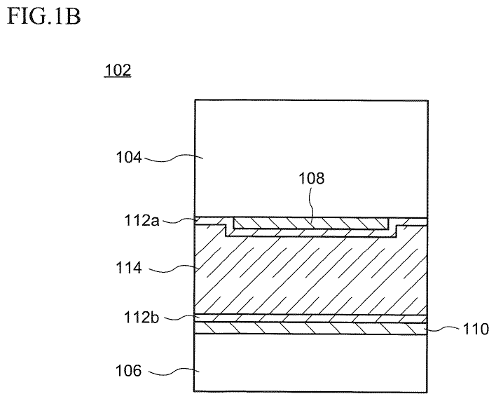

FIG. 1A and FIG. 1B show a reflecting element 102 used in a reflecting device 100 according to an embodiment of the present invention. FIG. 1A shows a plan view of the reflecting element 102 viewed from above (a side where radio waves enter), and FIG. 1B shows a cross-sectional view between A1-A2 shown in a plan view.

As shown in FIG. 1A and FIG. 1B, the reflecting element 102 includes a dielectric substrate 104, a counter substrate 106, a patch electrode 108, a common electrode 110, a first alignment film 112a, a second alignment film 112b, a liquid crystal layer 114, and a metal film 116. In the reflecting element 102, the dielectric substrate 104 can be regarded as a dielectric layer as it forms a single layer. The patch electrode 108 is arranged on the dielectric substrate 104, and the common electrode 110 is arranged on the counter substrate 106. The common electrode 110 is disposed on the back side of the patch electrode 108. The first alignment film 112a is arranged on the dielectric substrate (dielectric layer) 104 to cover the patch electrode 108, and the second alignment film 112b is arranged on the counter substrate 106 to cover the common electrode 110. The patch electrode 108 and the common electrode 110 are arranged to face each other, and the liquid crystal layer 114 is sandwiched between the patch electrode 108 and the common electrode 110. The first alignment film 112a is arranged on the dielectric substrate 104 between the patch electrode 108 and the liquid crystal layer 114, and the second alignment film 112b is arranged on the counter substrate 106 between the common electrode 110 and the liquid crystal layer 114.

The patch electrode 108 is preferably symmetrical with respect to the vertical and horizontal polarization of the incoming radio wave, and has a square or circular shape in a plan view. FIG. 1A shows the case where the patch electrode 108 has a square shape when seen in a plan view. There is no particular limitation to the shape of the common electrode 110 and it may have a shape in which almost the entire surface of the counter substrate 106 widens to have an area wider than the patch electrode 108. There is no limitation on materials used to form the patch electrode 108 and the common electrode 110, which may be formed using conductive metals and metal oxides. The dielectric substrate (dielectric layer) 104 may have a first wiring 118. The first wiring 118 is connected to the patch electrode 108. The first wiring 118 can be used to apply a control signal to the patch electrode 108. The first wiring 118 can also be used to connect one patch electrode to an adjacent patch electrode when multiple reflecting elements are arranged.

Although not shown in FIG. 1A and FIG. 1B, the dielectric substrate (dielectric layer) 104 and the counter substrate 106 are bonded together by a sealant. A distance between the dielectric substrate (dielectric layer) 104 and the counter substrate 106 is 20 to 100 μm, for example, a distance of 50 μm in this case. Since the patch electrode 108, the common electrode 110, the first alignment film 112a, and the second alignment film 112b are disposed between the dielectric substrate (dielectric layer) 104 and the counter substrate 106, the distance between the first alignment film 112a and the second alignment film 112b disposed on each of the dielectric substrate (dielectric layer) 104 and the counter substrate 106 is precisely the thickness of the liquid crystal layer 114. Although not shown in FIG. 1B, a spacer may be disposed between the dielectric substrate (dielectric layer) 104 and the counter substrate 106 to keep the distance constant.

A control signal is applied to the patch electrode 108 to align liquid crystal molecules in the liquid crystal layer 114. The metal electrode 116 is supplied with a potential independent of these signals and is in a floating state. The control signal is a DC voltage signal or a polarity inversion signal in which positive and negative DC voltages are alternately inverted. The common electrode 110 is applied with a voltage at ground or at an intermediate level of the polarity reversal signal. When the control signal is applied to the patch electrode 108, the alignment state of the liquid crystal molecules contained in the liquid crystal layer 114 is changed. Liquid crystal materials having dielectric constant anisotropy are used for the liquid crystal layer 114. For example, nematic, smectic, cholesteric, and discotic liquid crystals are used as the liquid crystal layer 114. The liquid crystal layer 114 with dielectric constant anisotropy has a dielectric constant that changes due to changes in the alignment state of the liquid crystal molecules. The reflecting element 102 can change the dielectric constant of the liquid crystal layer 114 by the control signal applied to the patch electrode 108, thereby delaying the phase of the reflected wave when radio waves are reflected.

The frequency bands of radio waves reflected by the reflecting element 102 are the very short wave (VHF) band, ultra short wave (UHF) band, microwave (SHF) band, submillimeter wave (THF), and millimeter wave (EHF) band. Although the liquid crystal molecules in the liquid crystal layer 114 align themselves in response to the control signal applied to the patch electrode 108, they hardly follow the frequency of the radio waves irradiated to the patch electrode 108. Therefore, the reflecting element 102 can control the phase of the reflected radio waves without being affected by radio waves.

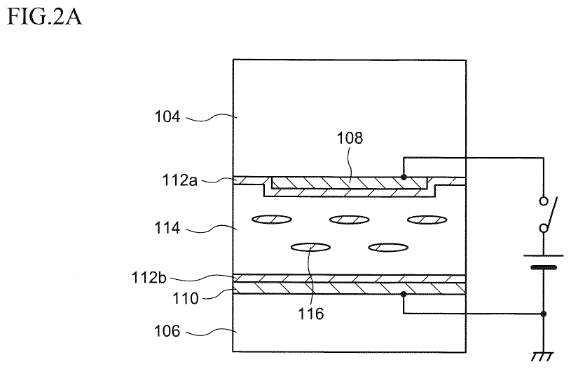

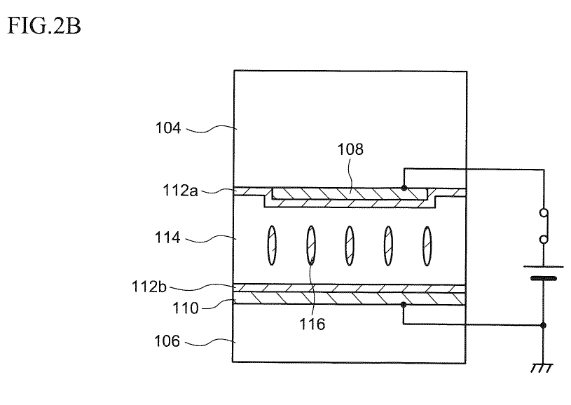

FIG. 2A shows a state (“first state”) in which a voltage is not applied between the patch electrode 108 and the common electrode 110. At this time, the metal film 116 is in a floating state. FIG. 2A shows an example where the first alignment film 112a and the second alignment film 112b are horizontally aligned films. The long axis of the liquid crystal molecules 116 in the first state is aligned horizontally with respect to the surfaces of the patch electrode 108 and the common electrode 110 by the first alignment film 112a and the second alignment film 112b. FIG. 2B shows a state (“second state”) in which a control signal (voltage signal) is applied to the patch electrode 108. Again, the metal film 116 is in a floating state. The liquid crystal molecules 116 are aligned in the second state with the long axis perpendicular to the surfaces of the patch electrode 108 and the common electrode 110 under the effect of the electric field. According to the magnitude of the control signal applied to the patch electrode 108 (magnitude of the voltage between the counter electrode and the patch electrode), it is possible to align the angle at which the long axis of the liquid crystal molecules 116 is aligned in an intermediate direction between the horizontal and vertical directions.

When the liquid crystal molecules 116 have positive dielectric constant anisotropy, the dielectric constant is greater in the second state relative to the first state. When the liquid crystal molecules 116 have negative dielectric constant anisotropy, the dielectric constant is smaller in the second state relative to the first state. The liquid crystal layer 114 having dielectric anisotropy can be regarded as a variable dielectric layer. The reflecting element 102 can be controlled to delay (or not) the phase of the reflected wave by using the dielectric constant anisotropy of the liquid crystal layer 114.

The reflecting element 102 is used for a reflector that reflects radio waves in a specified direction. The reflecting element 102 should attenuate the amplitude of the reflected radio waves as little as possible. As is clear from the structure shown in FIG. 1B, when a radio wave propagating in the air is reflected by the reflecting element 102, the radio wave passes through the dielectric substrate (dielectric layer) 104 twice. The dielectric substrate (dielectric layer) 104 is formed of a dielectric material such as glass or resin, for example.

### 2. Reflecting Device

Next, the structure of the reflecting device in which the reflecting elements are integrated is shown.

### 2-1. Reflecting Device a (Uniaxial Reflection Control)

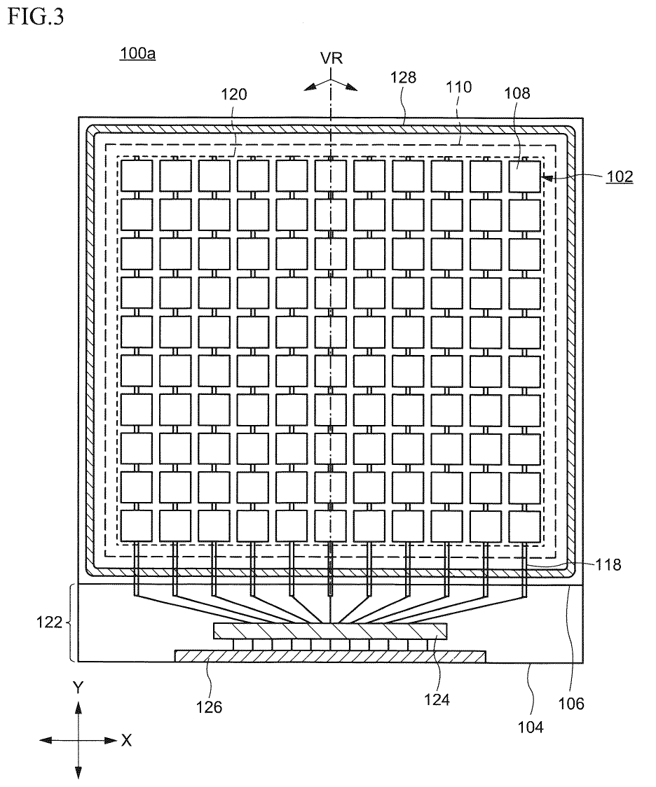

FIG. 3 shows a configuration of a reflecting device 100a according to an embodiment of the present invention. The reflecting device 100a includes a radio wave reflector 120. The radio wave reflector 120 is configured with a plurality of reflecting elements 102. The plurality of reflecting elements 102 are arranged, for example, in a column direction (X-axis direction shown in FIG. 3) and in a row direction (Y-axis direction shown in FIG. 3) that intersects the column direction. The plurality of reflecting elements 102 are arranged so that the patch electrodes 108 face the plane of incidence of radio waves. The radio wave reflector 120 is flat, and the plurality of patch electrodes 108 are arranged in this flat plane in a matrix.

The reflecting device 100a has a structure in which a plurality of reflecting elements 102 are integrated on a single dielectric substrate (dielectric layer) 104. The reflecting device 100 has a structure in which the plurality of reflecting elements 102 are integrated on a single dielectric substrate 104. As shown in FIG. 3, the reflecting device 100 has a structure in which the dielectric substrate 104 with an array of the plurality of patch electrodes 108 and the counter substrate 106 with the common electrode 110 are arranged on top of each other, and the liquid crystal layer (not shown) is disposed between the two substrates. The radio wave reflector 120 is formed in the region where the plurality of patch electrodes 108 and the common electrode 110 are superimposed. A cross-sectional structure of the radio wave reflector 120 is the same as that of the reflecting element 102 shown in FIG. 1B when viewed with respect to the individual patch electrodes 108. The dielectric substrate (dielectric layer) 104 and the counter substrate 106 are bonded to each other by the sealant 128, and the liquid crystal layer, not shown, is disposed in the region inside the sealant 128.

The dielectric substrate (dielectric layer) 104 has a peripheral area 122 that extends outward from the counter substrate 106 in addition to the area that faces the counter substrate 106. The peripheral region 122 is disposed with a first driver circuit 124 and a terminal part 126. The first driver circuit 124 outputs control signals to the patch electrode 108. The terminal part 126 is a region that forms a connection with an external circuit, for example, a connected flexible printed circuit board, not shown. Signals controlling the first driver circuit 124 are input to the terminal part 126.

As described above, the plurality of patch electrodes 108 is arranged on the dielectric substrate 104 in the column direction (X-axis) and the row direction (Y-axis). A plurality of first wirings 118 extending in the row direction (Y-axis direction) are arranged on the dielectric substrate 104. Each of the plurality of first wirings 118 is electrically connected to the plurality of patch electrodes 108 arranged in the row direction (Y-axis direction). In other words, the plurality of patch electrodes 108 arranged in the row direction (Y-axis direction) are connected by the first wiring 118. The radio wave reflector 120 has a configuration of a plurality of patch electrodes arrayed in a single row connected by the first wiring 118 in the column direction (X-axis direction).

The plurality of first wirings 118 arranged on the radio wave reflector 120 extend to the peripheral region 122. The first driver circuit 124 outputs control signals to be applied to the patch electrode 108. The first driver circuit 124 can output control signals of different voltage levels to each of the plurality of first wirings 118. As a result, the control signal is applied to the plurality of patch electrodes 108 arrayed in the first (X-axis) and second (Y-axis) directions in the radio wave reflector 120, row by row (for each patch electrode 108 arranged in the row direction (Y-axis)).

A control signal is applied to each pair of the plurality of patch electrodes 108 arranged in the row direction (Y-axis direction) in the reflecting device 100a. Thereby, the direction of reflection of the reflected wave of a radio wave incident on the radio wave reflector 120 can be controlled. That is, the reflecting device 100a can control the direction of travel of the reflected wave in the left and right directions on the drawing with respect to the reflection axis VR, which is parallel to the row direction (Y-axis direction), of the radio wave irradiated on the radio wave reflector 120.

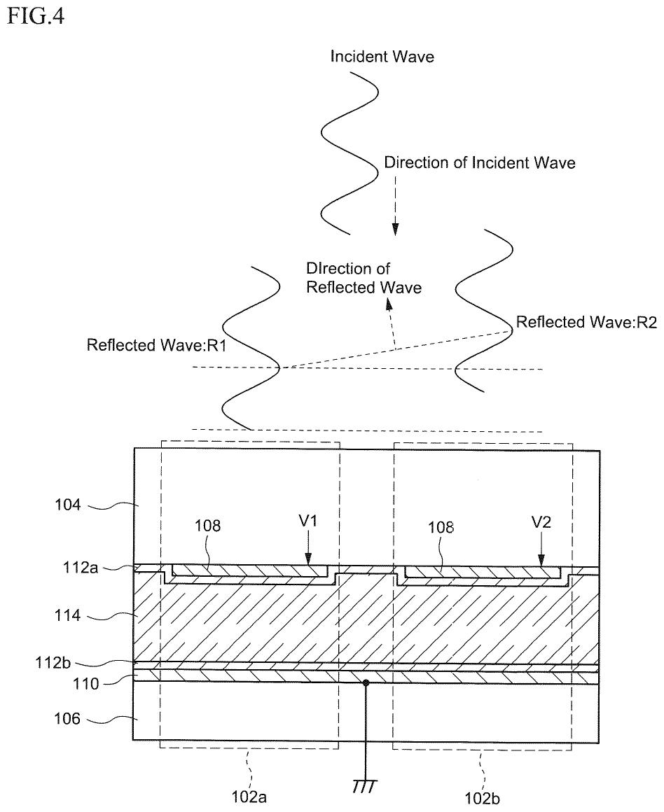

FIG. 4 schematically shows that the direction of travel of the reflected wave is changed by the two reflecting elements 102. In the case where radio waves are incident on the first reflecting element 102a and the second reflecting element 102b at the same phase, since different control signals (V1≠V2) are applied to the first reflecting element 102a and the second reflecting element 102b, the phase change of the reflected wave by the second reflecting element 102b is greater than that of the first reflecting element 102a. As a result, the phase of the reflected wave R1 reflected by the first reflecting element 102a and the phase of the reflected wave R2 reflected by the second reflecting element 102b differ (in FIG. 4, the phase of the reflected wave R2 is more advanced than that of the reflected wave R1), and the apparent traveling direction of the reflected wave changes obliquely.

Such a principle can be applied to the radio wave reflector 100a shown in FIG. 3 to control the direction of reflection in a uniaxial direction, for example, by controlling the amount of phase change by the reflecting elements on a column-by-column basis.

### 2-2. Reflecting Device B (Biaxial Reflection Control)

Since the reflecting device 100a has a single reflection axis VR, the reflection angle can be controlled in the direction with the reflection axis VR as the axis of rotation. In contrast, this embodiment shows an example of a reflecting device 100b that is capable of biaxial reflection control. In the following description, the focus will be on the parts that differ from the reflecting device 100a.

The reflecting device 100b has a plurality of second wirings 132 extending in the column direction (X-axis direction). The plurality of first wirings 118 and the plurality of second wirings 132 are arranged to intersect across an insulating layer not shown in the diagram. The plurality of first wirings 118 are connected to a first driver circuit 124, and the plurality of second wirings 132 are connected to a second driver circuit 130. The second driver circuit 130 outputs scanning signals.

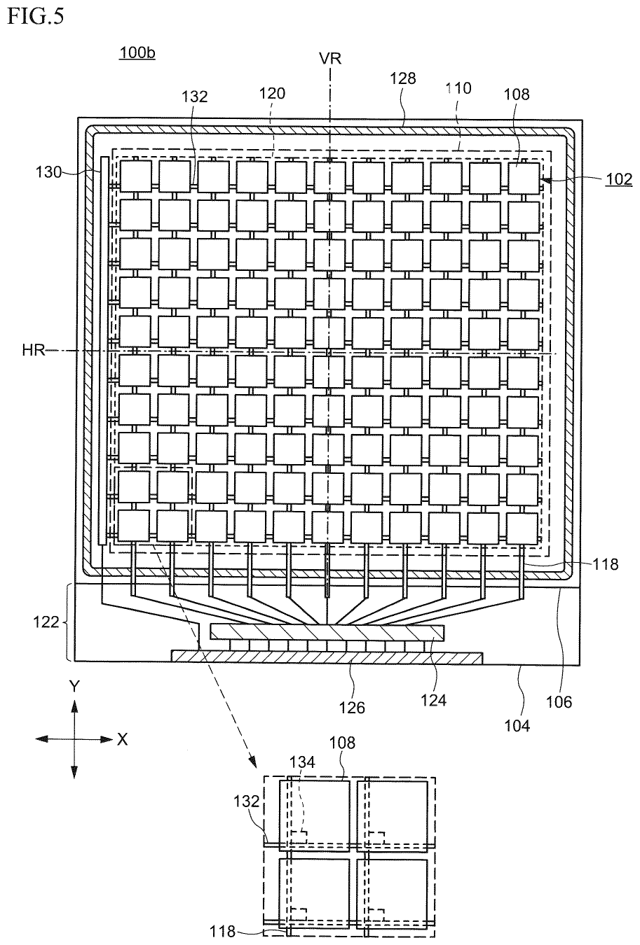

FIG. 5 shows an enlarged inset of the arrangement of the four patch electrodes 108, the first wirings 118 and the second wirings 132. Each of the four patch electrodes 108 is disposed with a switching element 134. Switching (on and off) of the switching element 134 is controlled by the scanning signal applied to the second wiring 132. A control signal is applied from the first wiring 118 to the patch electrode 108 where the switching element 134 is turned on. The switching element 134 is formed, for example, by a thin-film transistor. According to this configuration, the plurality of patch electrodes 108 arranged in the column direction (X-axis direction) can be selected row by row, and control signals of different voltage levels can be applied to each row.

The reflecting device 100b shown in FIG. 5 can control the direction of travel of the reflected wave in the left and right directions on the drawing, centered on the reflection axis VR parallel to the row direction (Y-axis direction), when the radio wave is irradiated on the radio wave reflector 120, and furthermore, the direction of travel of the reflected wave can also be controlled in the vertical direction on the drawing, centered on the reflection axis HR parallel to the column direction (X-axis direction). That is, since the reflecting device 100b has the reflection axis VR parallel to the row direction (Y-axis direction) and the reflection axis HR parallel to the column direction (X-axis direction), the reflection angle can be controlled in the direction with the reflection axis VR as the axis of rotation and in the direction with the reflection axis HR as the axis of rotation.

Such principles can be applied to the radio wave reflector 100b shown in FIG. 5 to control the direction of reflection in uniaxial and biaxial directions, for example, by controlling the amount of phase change by the reflecting element 102 independently in both columns and rows.

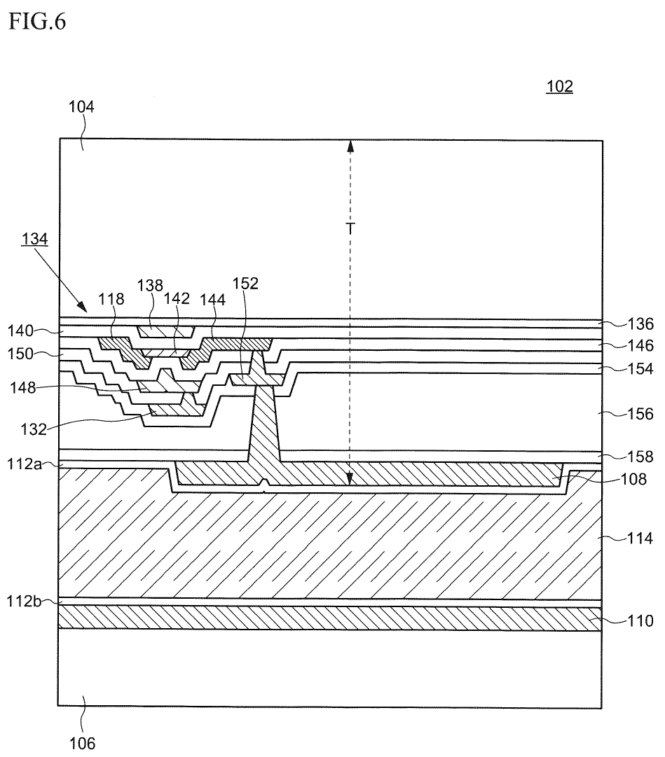

FIG. 6 shows an example of the cross-sectional structure of the reflecting element 102 with the switching element 134 connected to the patch electrode 108. The switching element 134 is disposed on the dielectric substrate (dielectric layer) 104. The switching element 134 is a transistor and has a stacked structure of a first gate electrode 138, a first gate insulating layer 140, a semiconductor layer 142, and a second gate electrode 148. An undercoat layer 136 may be disposed between the first gate electrode 138 and the dielectric substrate (dielectric layer) 104. The first wiring 118 is disposed between the first gate insulating layer 140 and the second gate insulating layer 146. The first wiring 118 is disposed in contact with the semiconductor layer 142. A first connecting wiring 144 is disposed on the same layer as the conductive layer forming the first wiring 118. The first connecting wiring 144 is disposed in contact with the semiconductor layer 142. The connection structure of the first wiring 118 and the first connecting wiring 144 to the semiconductor layer 142 shows a structure in which one wiring is connected to the source of the transistor and the other wiring is connected to the drain.

A first interlayer insulating layer 150 is disposed to cover the switching element 134. The second wiring 132 is disposed on the first interlayer insulating layer 150. The second wiring 132 is connected to the second gate electrode 148 through a contact hole formed in the first interlayer insulation layer 150. Although not shown in the figure, the first gate electrode 138 and the second gate electrode 148 are electrically connected to each other in a region that does not overlap the semiconductor layer 142. A second connecting wiring 152 is disposed on the first interlayer insulating layer 150 with the same conductive layer as the second wiring 132. The second connecting wiring 152 is connected to the first connecting wiring 144 through a contact hole formed in the first interlayer insulating layer 150.

A second interlayer insulating layer 154 is disposed to cover the second wiring 132 and the second connecting wiring 152. Furthermore, a planarization layer 156 is disposed to fill the steps of the switching element 134. It is possible to form the patch electrode 108 without being affected by the arrangement of the switching element 134 by arranging the planarization layer 156. A passivation layer 158 is disposed over the flat surface of the planarization layer 156. The patch electrode 108 is disposed over the passivation layer 158. The patch electrode 108 is connected to the second connecting wiring 152 through a contact hole formed through the passivation layer 158, the planarization layer 156, and the second interlayer dielectric layer 154. The first alignment film 112a is disposed over the patch electrode 108.

The counter substrate 106 is provided with the common electrode 110 and the second alignment film 112b, as shown in FIG. 1B. The surface on which the switching element 134 and the patch electrode 108 of the dielectric substrate (dielectric layer) 104 are provided is arranged so that the surface on which the common electrode 110 of the counter substrate 106 is provided faces the surface switching element 134, and the liquid crystal layer 114 is provided between them. A thickness T of the dielectric substrate (dielectric layer) 104 can be the length from the surface of the liquid crystal layer 114 side of the patch electrode 108 to the opposite side of the dielectric substrate (dielectric layer) 104 to the side on which the patch electrode 108 is provided. In this case, the thickness of at least one insulating layer (the undercoat layer 136, the first gate insulating layer 140, the second gate insulating layer 146, the first interlayer insulating layer 150, the second interlayer insulating layer 154, the planarization layer 156, and the passivation layer 158) between the patch electrode 108 and the dielectric substrate (dielectric layer) 104 can be taken into account.

Each layer formed on the dielectric substrate (dielectric layer) 104 is formed using the following materials. The undercoat layer 136 is formed, for example, with a silicon oxide film. The first gate insulating layer 140 and the second gate insulating layer 146 are formed, for example, with a silicon oxide film or a laminated structure of a silicon oxide film and a silicon nitride film. The semiconductor layers are formed of silicon semiconductors such as amorphous silicon and polycrystalline silicon, and oxide semiconductors including metal oxides such as indium oxide, zinc oxide, and gallium oxide. The first gate electrode 138 and the second gate electrode 148 may be configured, for example, of molybdenum (Mo), tungsten (W), or alloys thereof. The first wiring 118, the second wiring 132, the first connecting wiring 144, and the second connecting wiring 152 are formed using metal materials such as titanium (Ti), aluminum (Al), and molybdenum (Mo). For example, a titanium (Ti)/aluminum (Al)/titanium (Ti) laminate structure or a molybdenum (Mo)/aluminum (Al)/molybdenum (Mo) laminate structure may be used. The planarization layer 156 is formed of a resin material such as acrylic, polyimide, or the like. The passivation layer 158 is formed of, for example, a silicon nitride film. The patch electrode 108 and the common electrode 110 are formed of a metal film such as aluminum (Al), copper (Cu), or a transparent conductive film such as indium tin oxide (ITO).

As shown in FIG. 6, it is possible to select a predetermined patch electrode from the plurality of patch electrodes 108 arranged in a matrix and apply a control signal to the patch electrode, by connecting the second wiring 132 to the gate of the transistor used as the switching element 134, the first wiring 118 to one of the source and drain of the transistor, and the patch electrode 108 to the other of the source and drain. Then, it is possible to apply a control voltage to each patch electrode 108 arranged in a row along the column direction (x-axis direction) or each patch electrode 108 arranged in a row along the row direction (y-axis direction), by arranging the switching element 134 for each individual patch electrode 108 in the radio wave reflector 120, for example, when the radio wave reflector 120 is upright, the direction of reflection of the reflected wave can be controlled in the left-right and vertical directions.

### 3. Method for Inspecting Reflecting Device

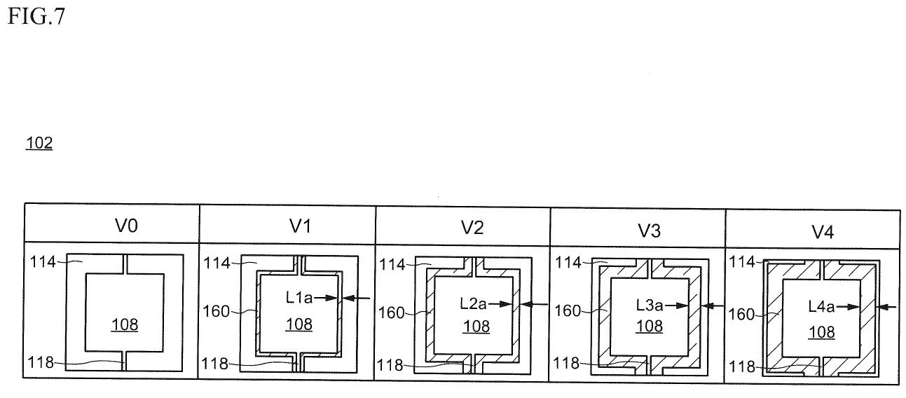

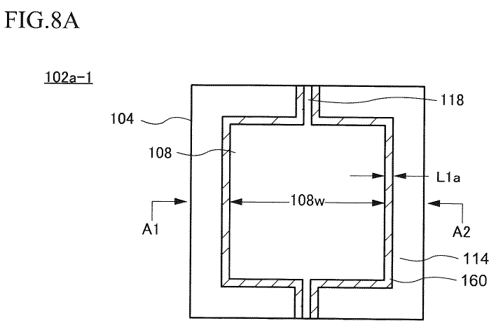

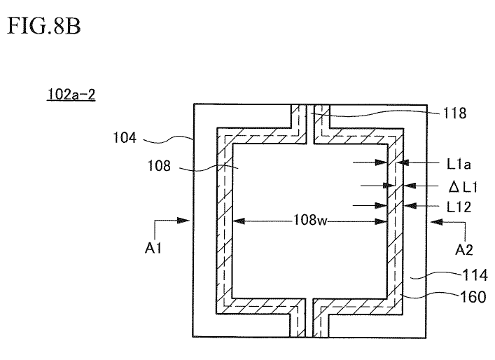

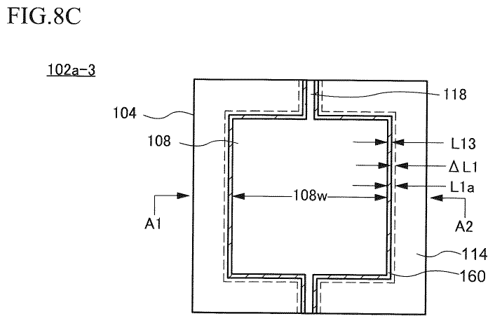

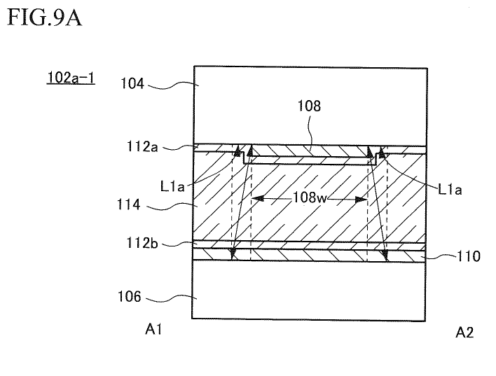

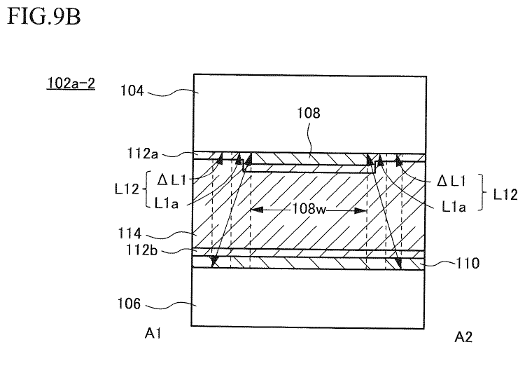

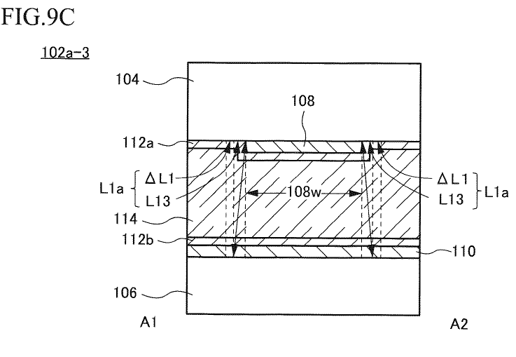

Next, a method for inspecting the reflecting device 100 is described with reference to FIG. 7, FIG. 8A through FIG. 8C, and FIG. 9A through FIG. 9C.

First, the reflecting device 100 is installed in the inspection device so that the patch electrode 108 can be observed from the top surface, with the direction of the patch electrode 108 as the top surface. Specifically, the reflecting device 100 is installed so that the patch electrode 108 is on the top surface and the common electrode 110 is on the bottom surface, as in the reflecting element 102 shown at the voltage V0 in FIG. 7.

The inspection device can be any microscope capable of nondestructively observing the reflecting device 100, for example, an optical microscope can be used. When an optical microscope is used to observe the reflecting device 100, the patch electrode 108 and its surroundings can be observed from the top surface with reflected light because the common electrode 110 of the reflective device 100 is often made of conductive metal or other materials that are impermeable to the common electrode 110.

Furthermore, the inspection device should have an image capturing function to capture shape information of the reflecting elements 102 to be observed. With this function, the shape information of the observed reflecting elements 102 can be batch processed with images when the reflecting device 100 has a large area or when the observation and inspection of the reflecting device 100 are not performed at the same time.

The inspection equipment is then adjusted so that the width or horizontal and vertical lengths of the 108 patch electrodes of the reflecting element 102 can be measured. For example, if the patch electrode 108 is rectangular, the inspection device should be adjusted so that it can measure about one-twentieth the size of the long or short side. In this case, there is no need to install a polarizer or other optical filter in the inspection device. Unlike the observation of a display device using liquid crystals, the observation of the reflecting device 100 in the present embodiment can be performed without optical filters.

Next, voltages V0 to V4 are applied between the patch electrode 108 and the common electrode 110, and the reflecting element 102 is observed. In the present embodiment, voltage V0 indicates that the voltage between the patch electrode 108 and the common electrode 110 is 0 V and the application of the voltage 0 V is also included in the application of voltages. The voltages V0 to V4 are different from each other. Furthermore, the absolute values of the respective voltages V0 to V4 are greater in the order of voltage V0 to voltage V4. These applied voltages are not limited to the voltages V0 to V4, and can be set as appropriate to the extent that the reflecting element 102 can be set from low phase difference to high phase difference.

Finally, the quality determination of the reflecting element 102 is based on the change (to be described later) in the frame region that appears on the periphery of the patch electrode 108 on the application of the voltages described above.

### <Criteria for Determination>

First, referring to FIG. 7, the reflecting element 102, in which the desired voltage corresponding to the voltage applied between the patch electrode 108 and the common electrode 110 is applied to the liquid crystal layer, will be explained.

A voltage V0 is applied between the patch electrode 108 and the common electrode 110, or the voltage between the patch electrode 108 and the common electrode 110 of the reflecting element 102 is not applied. When the reflecting element 102 is observed from the top surface, the frame region 160 does not appear around the periphery of the patch electrode 108, as in the reflecting element 102 shown at the voltage V0 in FIG. 7.

A voltage V1 is applied between the patch electrode 108 and the common electrode 110. When the reflecting element 102 is observed from the top surface, a frame region 160 with a width L1a appears around the periphery of the patch electrode 108, as shown at the voltage V1 in FIG. 7. The frame region 160 surrounds the patch electrode 108 in the top view. Further, the frame region 160 may appear along the first wiring 118 connecting to the patch electrode 108 with the same width. The width L1a is the width of the frame region 160 corresponding to the patch electrode 108 and the common electrode 110 when the voltage V1 is normally applied between the patch electrode 108 and the common electrode 110, which is the reference for quality determination of the frame region 160.

A voltage V2 is applied between the patch electrode 108 and the common electrode 110. When the reflecting element 102 is observed from the top surface, a frame region 160 with a width L2a appears on the periphery of the patch electrode 108, as in the reflecting element 102 shown in FIG. 7 at the voltage V2. Furthermore, the frame region 160 may appear along the first wiring 118 connecting to the patch electrode 108 with the same width. The width L2a is the width of the corresponding frame region 160 when the voltage V2 is normally applied between the patch electrode 108 and the common electrode 110, which is the reference for quality determination of the frame region 160. The reference width L2a is greater than the reference width L1a, similar to the relationship where the absolute value of the voltage V2 is greater than the absolute value of the voltage V1. The fact that the absolute value of the voltage V2 is greater than the absolute value of the voltage V1 allows the reflecting element 102 to set a higher phase change than the phase change set for the reflecting element 102 with the voltage V1 applied between the patch electrode 108 and the common electrode 110.

A voltage V3 is applied between the patch electrode 108 and the common electrode 110. When the reflecting element 102 is observed from the top surface, a frame region 160 with a width L3a appears on the periphery of the patch electrode 108, as shown at the voltage V3 in FIG. 7. Furthermore, the frame region 160 may appear along the first wiring 118 connecting to the patch electrode 108 with the same width. The width L3a is the width of the corresponding frame region 160 when the voltage V3 is normally applied between the patch electrode 108 and the common electrode 110, which is the reference for quality determination of the frame region 160. The reference width L3a is greater than the reference width L2a, similar to the relationship where the absolute value of the voltage V3 is greater than the absolute value of the voltage V2. The absolute value of the voltage V3 being greater than the absolute value of the voltage V2 allows the reflecting element 102 to set a higher phase change than the phase change set for the reflecting element 102 with the voltage V2 applied between the patch electrode 108 and the common electrode 110.

A voltage V4 is applied between the patch electrode 108 and the common electrode 110. When the reflecting element 102 is observed from the top surface, a frame region 160 appears around the periphery of the patch electrode 108, as shown at the voltage V4 in FIG. 7. Furthermore, the frame region 160 may appear along the first wiring 118 connecting to the patch electrode 108 with the same width. When the width of the frame region 160 that appeared was measured, the width of the frame region 160 was a width L4a. Here, the width L4a is the width of the corresponding frame region 160 when the voltage V4 is normally applied between the patch electrode 108 and the common electrode 110, which is the reference for quality determination of the frame region 160. The reference width L4a is greater than the reference width L3a, similar to the relationship where the absolute value of the voltage V4 is greater than the absolute value of the voltage V3. The absolute value of the voltage V4 being greater than the absolute value of the voltage V3 allows the reflecting element 102 to set a higher phase change than the phase change set for the reflecting element 102 with the voltage V3 applied between the patch electrode 108 and the common electrode 110.

The reference widths L1a to L4a can be determined by measuring the frame region 160 from the actually fabricated reflecting device 100 at the respective applied voltages as described above. The reference widths L1a to L4a can also be determined by calculating from design criteria in consideration of the size of the patch electrode 108 of the reflecting device 100 and the physical properties of the thickness of the cell for the liquid crystal layer. The reference widths L1a to L4a can be determined without being limited to the above-described method in particular.

Next, the details of the quality determination of the reflecting element 102 based on the change in the frame region 160 will be explained using the reference widths L1a through L4a. The quality determination of the reflecting element 102 refers to the determination of whether the reflecting element 102 is good or bad, and that the desired voltage is normally applied to the liquid crystal layer 114, or that the desired voltage is not normally applied to the liquid crystal layer 114.

Referring to FIGS. 8A through 8C, examples of the reflecting element 102 in which it can be determined that the voltage V1 is normally applied to the liquid crystal layer 114 are illustrated below. FIG. 8A shows a plan view of a reflecting element 102a-1 in which a frame region 160 of the reference width L1a appears. Next, FIG. 8B shows a reflecting element 102a-2 in which a frame region 160 with a width L12, which is greater than the reference width L1a by ΔL1, appears. Furthermore, FIG. 8C shows the reflecting element 102a-3 with the appearance of a frame region L13 that is smaller than the reference width L1a by ΔL1. Thus, if the width L12 or L13 of the frame region 160 is within ΔL1 difference from the reference width L1a, it can be determined that the voltage V1 is applied to the liquid crystal layer 114. Put another way, if the voltage V1 is applied between the patch electrode 108 and the common electrode 110 and the width of the frame region 160 is greater than the difference ΔL1 from the reference width L1a, then it can be determined that the voltage V1 is not normally applied to the liquid crystal layer in the reflecting element. FIGS. 8A through 8C show examples in which the width is uniformly increased or decreased with respect to the periphery of the patch electrode 108. However, the widths L12 and L13 of the frame region 160 do not have to be uniformly increased or decreased. If the difference between the widths is within ΔL1 from the reference width L1a, it can be determined that the voltage V1 is normally applied to the liquid crystal layer.

The value of ΔL1 can be determined by measuring the frame region 160 from the actually fabricated reflecting device 100 at the respective applied voltages as well as the reference width L1a. The value of ΔL1 can also be determined by calculating from design criteria in light of the size of the patch electrode 108 of the reflecting device 100 and the physical properties due to the thickness of the cell for the liquid crystal layer, etc. The method for determining ΔL1 is not limited to the method described above and is also the same for ΔL2 to ΔL4 described below.

Referring now to FIGS. 9A through 9C, the cross-sectional structure of the reflecting elements 102 shown in FIGS. 8A through 8C will be described. FIG. 9A shows a cross-sectional view of the reflecting element 102a-1 shown in FIG. 8A. As shown in FIG. 9A, the frame region 160 is the top surface of a part of the liquid crystal layer 114. The part of the liquid crystal layer 114 with the frame region 160 as its top surface is a liquid crystal oriented by the diagonal electric field (up and down arrows) formed between the patch electrode 108 and the common electrode 110 when the voltage V1 is applied between the patch electrode 108 and the common electrode 110. The diagonal electric field indicated by the up and down arrows is illustrative and not restrictive.

In detail, the part of the liquid crystal layer 114 with the frame region 160 as its top surface shows the orientation of the liquid crystal due to the leakage out of the diagonal electric field formed between the edge of the patch electrode 108 or its surroundings and the common electrode 110. The leakage out of a diagonal electric field refers to the electric field between the patch electrode 108 and the common electrode 110 that is formed outside of the width 108w compared to the electric field within the width 108w of the patch electrode 108, as shown in FIGS. 9A through 9C. Therefore, as shown in FIGS. 8A to 8C, the orientation of the liquid crystal due to those electric fields can be seen in the top view as a frame region 160 appearing around the periphery of the patch electrode 108, and it is possible to measure the width of the frame region 160, which changes depending on the voltage applied between the patch electrode 108 and the common electrode 110.

As shown in FIGS. 9A through 9C, a part of the liquid crystal layer 114 oriented by the electric field that is formed outside of the width 108w is positioned between the patch electrode 108 and the common electrode 110 so that the liquid crystal layer 114 oriented by the electric field within the width 108w of the patch electrode 108 is sandwiched between the patch electrode 108 and the common electrode 110.

The reflecting element 102a-2 shown in FIG. 8B will now be explained while referring to the cross-sectional view shown in FIG. 9B. Similarly in the reflecting element 102a-2, by applying the voltage V1 between the patch electrode 108 and the common electrode 110, a diagonal electric field (up and down arrows) is formed between the edge of the patch electrode 108 and the common electrode 110. The diagonal electric field formed causes a part of the liquid crystal layer that is not superimposed on the common electrode 110 to be oriented, and the oriented liquid crystal is visible in the top view as a frame region 160 of the width L12. In the reflecting element 102a-2, the diagonal electric field in the reflecting element 102a-1 spreads toward the common electrode 110 to a greater extent than that in the reflecting element 102a-1, but the width L12 of the frame region 160 is within ΔL1 of the reference width L1a. Since the difference is within ΔL1, it can be determined that the voltage is normally applied to the liquid crystal layer 114.

Furthermore, the reflecting element 102 shown in FIG. 8C is also explained with reference to the cross-sectional view shown in FIG. 9C. Similarly for a reflecting element 102a-3, by applying the voltage V1 between the patch electrode 108 and the common electrode 110, a diagonal electric field (up and down arrows) is formed between the edge of the patch electrode 108 and the common electrode 110. The diagonal electric field formed causes a part of the liquid crystal layer to be oriented, and the oriented liquid crystal is visible in the top view as a frame region 160 of a width L13. At this time, the diagonal electric field in the reflecting element 102a-3 is narrower toward the common electrode 110 than that in the reflecting element 102a-1, but the width L12 of the frame region 160 is within ΔL1 of the reference width L1a, so that the voltage is normally applied to the liquid crystal layer 114. It can be determined that the voltage is normally applied to the liquid crystal layer 114.

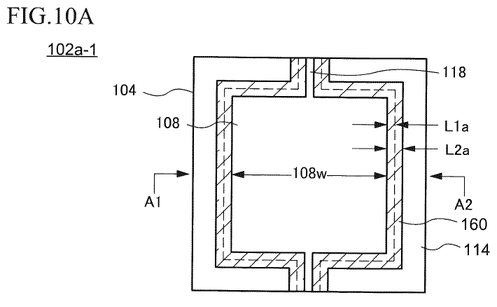

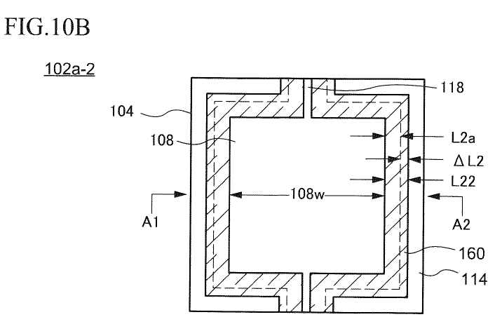

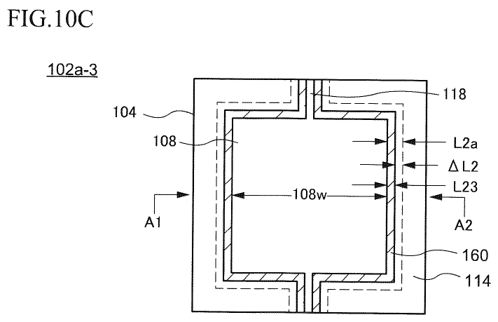

Referring now to FIGS. 10A through 10C, an example of a reflecting element 102 in which it can be determined that the voltage V2 is normally applied to the liquid crystal layer 114 will be described. The difference from the reflecting element 102 shown in FIGS. 8A to 8C and FIGS. 9A to 9C is that the absolute value of the voltage applied between the patch electrode 108 and the common electrode 110 is greater than the absolute value of the voltage V1. The same or similar configuration to the reflecting element 102 shown in FIGS. 8A to 8C and FIGS. 9A to 9C may be omitted from the description.

FIG. 10A shows a plan view of the reflecting element 102a-1 in which the voltage V2 is applied between the patch electrode 108 and the common electrode 110. As shown in FIG. 10A, the reference width L2a when the voltage V2 different from the voltage V1 is applied between the patch electrode 108 and the common electrode 110 shows a width different from the reference width La when the voltage V1 is applied between the patch electrode 108 and the common electrode 110. The reference width L2a is greater than the reference width L1a because the absolute value of the voltage V2 is greater than the absolute value of the voltage V1.

FIGS. 10B and 10C show the reflecting elements 102a-2 and 102a-3, respectively, in which the width of the frame region 160 has a difference of ΔL2 from the reference width L2a. FIG. 10B shows the reflecting element 102a-2 in which the boxed region 160 appears with a width L22 that is greater than the reference width L2a by ΔL2. Furthermore, FIG. 10C shows the reflecting element 102a-3 with the appearance of the frame region L23, which is smaller than the reference width L2a by ΔL2. Thus, if the width L22 or L23 of the frame region 160 is within ΔL2 difference from the reference width L2a, it can be determined that the voltage V2 is applied to the liquid crystal layer 114. In other words, if the voltage V1 is applied between the patch electrode 108 and the common electrode 110 and the width of the frame region 160 is greater than the difference ΔL2 from the reference width L2a, then it can be determined that the voltage V2 is not normally applied to the liquid crystal layer in the reflecting element.

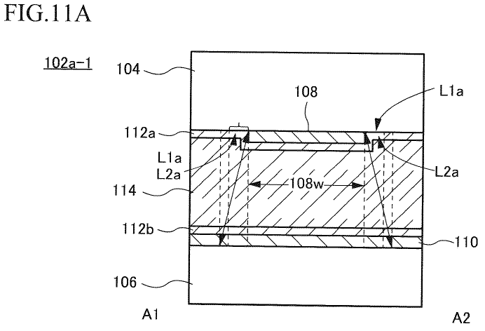

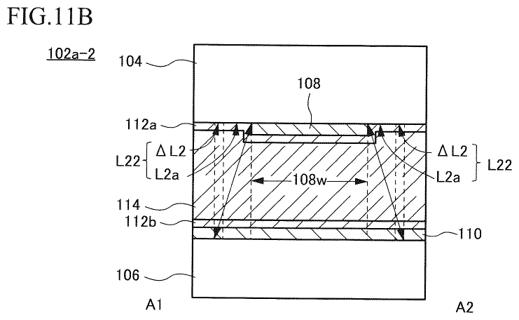

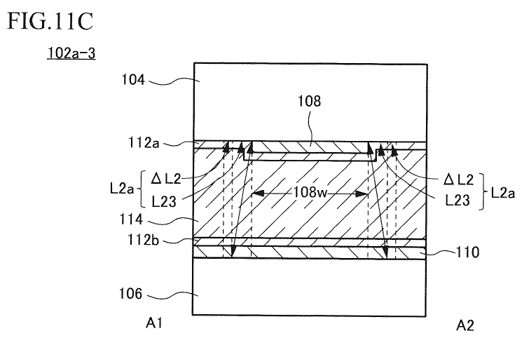

Referring now to FIGS. 11A through 11C, the cross-sectional structure of the reflecting element 102 shown in FIGS. 10A through 10C will be described. FIG. 11A shows a cross-sectional view of the reflecting element 102a-1 shown in FIG. 10A. As described above, since the voltage V2, which is greater than the voltage V1, is applied between the patch electrode 108 and the common electrode 110, the spread of the diagonal electric field (up and down arrows) between the patch electrode 108 and the common electrode 110 is greater than when the voltage V1 is applied. Therefore, the reference width L2a is greater than the reference width L1a.

FIG. 11B shows a cross-sectional view of the reflecting element 102a-2 shown in FIG. 10B. As shown in FIG. 11B, the diagonal electric field of the reflecting element 102a-2 spreads more toward the common electrode 110 than the diagonal electric field of the reflecting element 102a-1, but the width L22 of the frame region 160 is within ΔL2 of the reference width L2a, and therefore, it can be determined that the voltage is normally applied to the liquid crystal layer 11a-1 in the liquid crystal layer 114.

FIG. 11C shows a cross-sectional view of the reflecting element 102a-3 shown in FIG. 10C. As shown in FIG. 11C, the diagonal electric field of the reflecting element 102a-3 is smaller and spreads toward the common electrode 110 compared to the diagonal electric field of the reflecting element 102a-1, but the width L23 of the frame region 160 is within ΔL2 difference from the reference width L2a, so it can be determined that the voltage is normally applied to the liquid crystal layer 114.

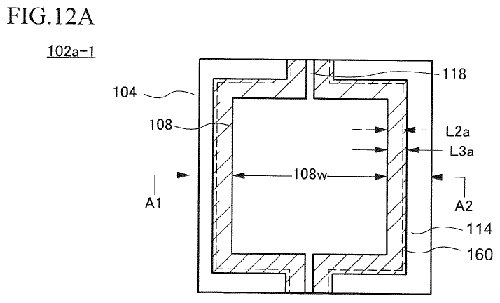

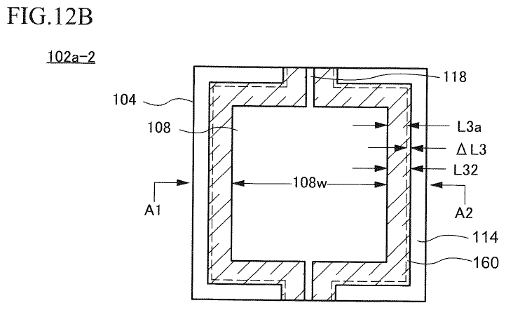

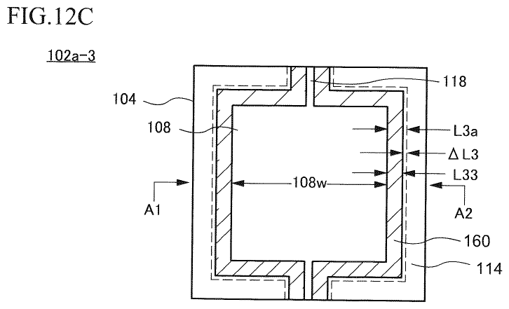

Referring now to FIGS. 12A through 12C, an example of a reflecting element 102 in which it can be determined that the voltage V3 is normally applied to the liquid crystal layer 114 will be described. The difference from the reflecting element 102 shown in FIGS. 10A to 10C and FIGS. 11A to 11C is that the absolute value of the voltage applied between the patch electrode 108 and the common electrode 110 is greater than the absolute value of the voltage V2. The same or similar configuration to the reflecting element 102 shown in FIGS. 10A through 10C and FIGS. 11A through 11C may be omitted from the description.

FIG. 12A shows a plan view of the reflecting element 102a-1 in which the voltage V2 is applied between the patch electrode 108 and the common electrode 110. As shown in FIG. 12A, the reference width L3a when the voltage V3 different from the voltage V2 is applied between the patch electrode 108 and the common electrode 110 shows a width different from the reference width L2a when the voltage V2 is applied between the patch electrode 108 and the common electrode 110. The reference width L3a is greater than the reference width L2a because the absolute value of the voltage V3 is greater than the absolute value of the voltage V2.

FIGS. 12B and 12C show the reflecting elements 102a-2 and 102a-3, respectively, in which the width of the frame region 160 has a difference of ΔL3 from the reference width L3a. FIG. 12B shows the reflecting element 102a-2 in which the frame region 160 appears with a width L32 that is ΔL3 greater than the reference width L3a. Furthermore, FIG. 12C shows the reflecting element 102a-3 with the appearance of the frame region L23, which is smaller than the reference width L3a by ΔL3. Thus, if the width L32 or L33 of the frame region 160 is within ΔL3 difference from the reference width L3a, it can be determined that the voltage V3 is applied to the liquid crystal layer 114. In other words, if the voltage V1 is applied between the patch electrode 108 and the common electrode 110 and the width of the frame region 160 is greater than the difference ΔL3 from the reference width L3a, then it can be determined that the voltage V3 is not normally applied to the liquid crystal layer in the reflecting element.

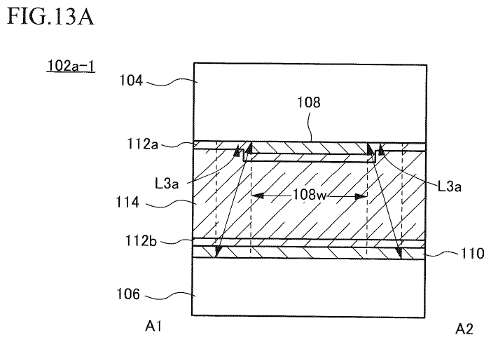

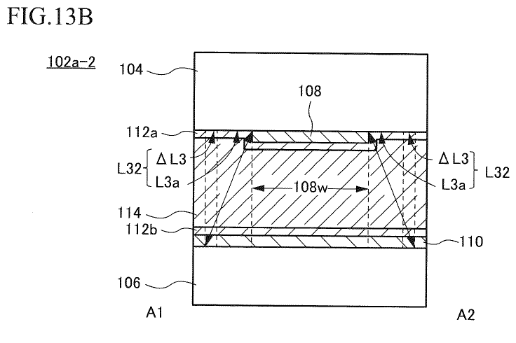

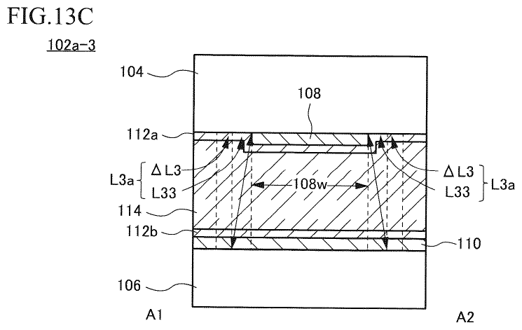

Referring now to FIGS. 13A through 13C, a cross-sectional structure of the reflecting element 102 shown in FIGS. 12A through 12C will be described. FIG. 13A shows a cross-sectional view of the reflecting element 102a-1 shown in FIG. 12A. As described above, since the voltage V3, which is greater than the voltage V2, is applied between the patch electrode 108 and the common electrode 110, the spread of the diagonal electric field (up and down arrows) between the patch electrode 108 and the common electrode 110 is greater than when the voltage V2 is applied. Therefore, the reference width L3a is greater than the reference width L2a.

FIG. 13B shows a cross-sectional view of the reflecting element 102a-2 shown in FIG. 12B. As shown in FIG. 13B, the diagonal electric field in the reflecting element 102a-2 spreads more toward the common electrode 110 than that in the reflecting element 102a-1. However, since the difference between the width L32 of the frame region 160 and the reference width L3a is within ΔL3, it can be determined that the voltage is normally applied to the liquid crystal layer 114.

FIG. 13C shows a cross-sectional view of the reflecting element 102a-3 shown in FIG. 12C. As shown in FIG. 13C, the diagonal electric field in the reflecting element 102a-3 spreads less toward the common electrode 110 than that in the reflecting element 102a-1. However, since the difference between the width L33 of the frame region 160 and the reference width L3a is within ΔL3, it can be determined that voltage is normally applied to the liquid crystal layer 114.

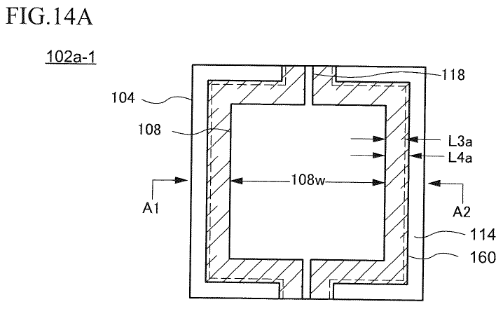

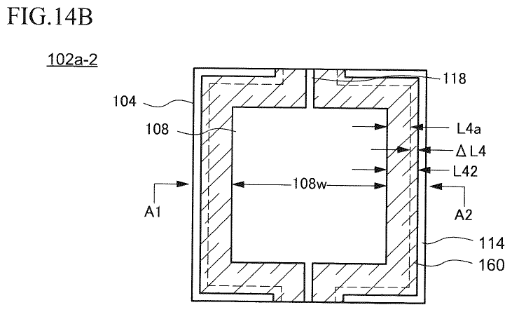

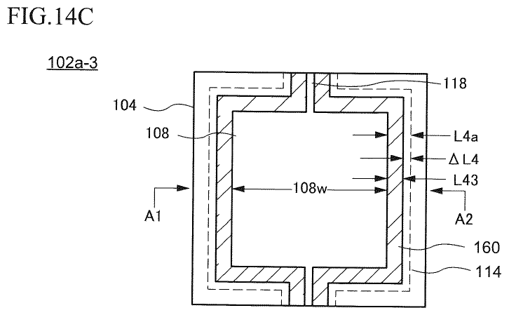

Referring now to FIGS. 14A through 14C, an example in which it can be determined that a voltage V4 is normally applied to the liquid crystal layer 114 in a reflecting element 102 will be described. The difference from the reflecting element 102 shown in FIGS. 12A to 12C and FIGS. 13A to 13C is that the absolute value of the voltage V4 applied between the patch electrode 108 and the common electrode 110 is greater than the absolute value of the voltage V3. The same or similar configuration to the reflecting element 102 shown in FIGS. 12A through 12C and FIGS. 13A through 13C may be omitted from the description.

FIG. 14A shows a plan view of the reflecting element 102a-1 in which the voltage V4 is applied between the patch electrode 108 and the common electrode 110. As shown in FIG. 14A, the reference width L4a when the voltage V4 different from the voltage V3 is applied between the patch electrode 108 and the common electrode 110 shows a width different from the reference width L3a when the voltage V3 is applied between the patch electrode 108 and the common electrode 110. The reference width L4a is greater than the reference width L3a as the absolute value of the voltage V4 is greater than the absolute value of the voltage V3.

FIGS. 14B and 14C show the reflecting elements 102a-2 and 102a-3, respectively, in which the width of the frame region 160 has a difference of ΔL4 from the reference width L4a. FIG. 14B shows the reflecting element 102a-2 in which the frame region 160 appears with a width of L42 that is ΔL4 larger than the reference width L4a. Furthermore, FIG. 14C shows the reflecting element 102a-3 with the appearance of the frame region L43, which is smaller than the reference width L4a by ΔL4. Thus, if the difference between the width L42 or L43 of the frame region 160 and the reference width L4a is within ΔL4, it can be determined that the voltage V4 is applied to the liquid crystal layer 114. In other words, if the voltage V4 is applied between the patch electrode 108 and the common electrode 110 and the difference between the width of the frame region 160 and the reference width L4a is greater than ΔL4, then it can be determined that the voltage V4 is not normally applied to the liquid crystal layer in the reflecting element.

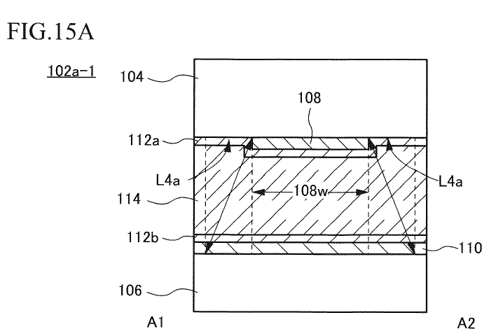

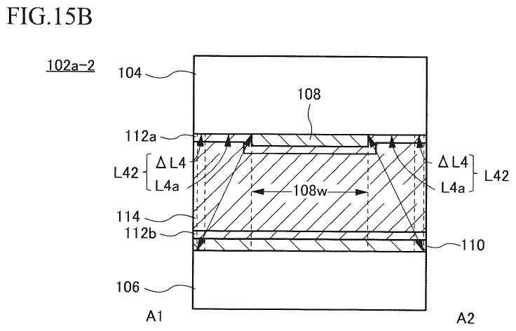

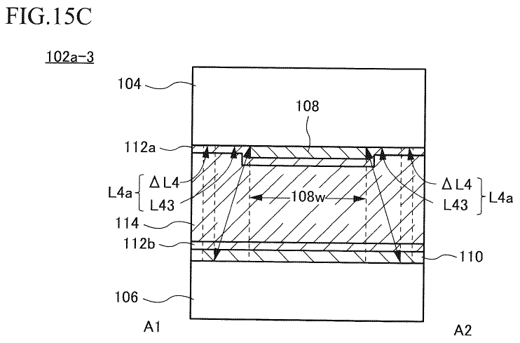

Referring now to FIGS. 15A through 15C, the cross-sectional structure of the reflecting element 102 shown in FIGS. 14A through 14C will be described. FIG. 15A shows a cross-sectional view of the reflecting element 102a-1 shown in FIG. 14A. As described above, the spread of the diagonal electric field (up and down arrows) between the patch electrode 108 and the common electrode 110 is greater than when the voltage V3 is applied since the voltage V4, which is greater than the voltage V3, is applied between the patch electrode 108 and the common electrode 110. Therefore, the reference width L4a is greater than the reference width L3a.

FIG. 15B shows a cross-sectional view of the reflecting element 102a-2 shown in FIG. 14B. As shown in FIG. 15b, the diagonal electric field of the reflecting element 102a-2 spreads more toward the common electrode 110 than the diagonal electric field of the reflecting element 102a-1. However, the difference between the width L42 of the frame region 160 and the reference width L4a is within ΔL4, so it can be determined that the voltage is normally applied to the liquid crystal layer 114.

FIG. 15C shows a cross-sectional view of the reflecting element 102a-3 shown in FIG. 14C. As shown in FIG. 15C, the diagonal electric field of the reflecting element 102a-3 spreads smaller toward the common electrode 110 than that of the reflecting element 102a-1. However, the difference between the width L43 of the frame region 160 and the reference width L4a is within ΔL4, so it can be determined that the voltage is normally applied to the liquid crystal layer 114.

As described above, the method for inspecting a radio wave reflecting device 100 in accordance with one embodiment of the present invention can determine whether each of the plurality of reflecting elements 102 of the radio wave reflecting device 100 is good or bad based on changes in the frame region 160 that appears around the periphery of the patch electrode 108 in a top view by applying a desired voltage between the patch electrode 108 and the common electrode 110 of each of the plurality of reflecting elements 102 of the radio wave reflecting device 100. Such quality determination can be used for inspection of the reflecting device 100 prior to shipment, etc., since the inspection of the reflecting device 100 can be performed nondestructively. Furthermore, by measuring the width of the frame region 160 that appears around the periphery of the patch electrode 108 in the top view, the failure mode of the reflecting element 102 can be determined. This determination of the failure mode enables failure analysis of the manufacturing process of the reflecting device 100 and further improves the yield of the reflecting device 100.

### 4. Failure Mode

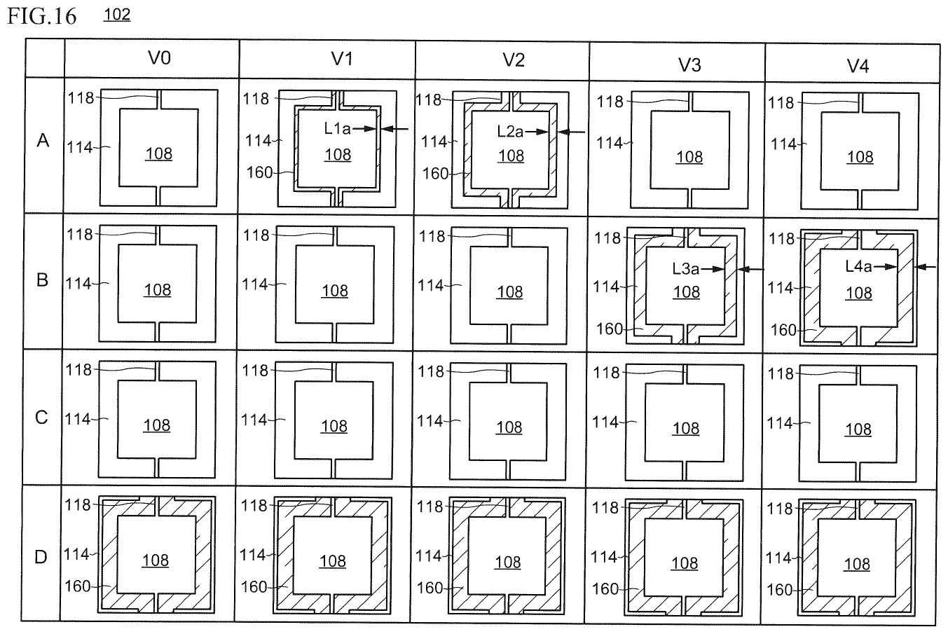

FIG. 16 shows an example of a plan view of the reflecting element 102 when the desired voltage is not applied to the liquid crystal layer 114.

Item A in FIG. 16 shows an example of a reflecting element 102 in a failure mode A. The frame region 160 appears with a specified width from the voltage V0 to the voltage V2 and disappears from the voltage V3 to the voltage V4, which are high potentials, when the voltage V0 to the voltage V4 are applied between the patch electrode 108 and the common electrode 110, respectively. The specified width indicates, for example, the width within the difference ΔL1 from the reference width L1a for the voltage V1 and the width within the difference ΔL2 from the reference width L2a for the voltage V2. In failure mode A, it is assumed that the electrical characteristics of the switching element 134 connected to the patch electrode 108 are faulty.

Item B in FIG. 16 shows an example of a reflecting element 102 in failure mode B. The frame region 160 does not appear from the voltage V0 to the voltage V2 and appears with a specified width from the voltage V3 to the voltage V4, which is a high potential, when the voltage V0 to the voltage V4 is applied between the patch electrode 108 and the common electrode 110, respectively. The specified width indicates, for example, the width within the difference ΔL3 from the reference width L3a for the voltage V3 and the width within the difference ΔL4 from the reference width L4a for the voltage V4. From the above, it can be seen that in failure mode B, the voltage applied to the liquid crystal layer is insufficient. The cause of the insufficient voltage is assumed to be a defect in the electrical characteristics of the switching element connected to the patch electrode 108. Also, although not shown in the figure, when a frame region with a width other than the specified width appears at the high potential as described above, the voltage applied to the liquid crystal layer is insufficient, and it is assumed that the electrical characteristics of the switching element connected to the patch electrode 108 are faulty.

Item C in FIG. 16 shows an example of a reflecting element 102 in failure mode C. The frame region 160 is applied between the patch electrode 108 and the common electrode 110 from voltage V0 to voltage V4, respectively, but there are no changes in the frame region 160. Specifically, the frame region 160 does not appear regardless of the applied voltages. From the above, it is assumed that in failure mode C, an open failure of the switching element connected to the patch electrode 108 and a connection failure between the patch electrode 108 and the switching element have occurred, etc.

Item D in FIG. 16 shows an example of a reflecting element 102 in failure mode D. The frame region 160 is applied between the patch electrode 108 and the common electrode 110 from voltage V0 to voltage V4, respectively, but there is no change in the frame region 160. Specifically, the frame region 160 appears regardless of the applied voltages. From the above, it is assumed that short-circuits between the source and drain or between the drain and gate of the switching element have occurred in failure mode D. Due to these short-circuits, the voltage from the signal line connected to the source or the gate line connected to the gate electrode is always directly applied to the liquid crystal layer, and it is assumed that a frame region appears regardless of whether the switching element is on or off.

As described above, the reflecting element 102 in which the desired voltage is not applied to the liquid crystal layer can be classified as a failure mode by observing the change in the frame region 160 due to the applied voltages.

Each of the embodiments described above as an embodiment of the present invention can be appropriately combined and implemented as long as no contradiction is caused. Further, the addition, deletion, or design change of components, or the addition, deletion, or condition change of process as appropriate by those skilled in the art based on the display device of each embodiment are also included in the scope of the present invention as long as they are provided with the gist of the present invention.

It is understood that other advantageous effects different from the advantageous effects disposed by the embodiments disclosed herein, which are obvious from the description herein or which can be easily foreseen by a person skilled in the art, will naturally be disposed by the present invention.

What is claimed is:

1. A method for inspecting a reflecting device,
the reflecting device comprising a plurality of reflecting elements arrayed in a matrix, each of the plurality of reflecting elements comprises a patch electrode, a common electrode on a back side of the patch electrode, and a liquid crystal layer between the patch electrode and the common electrode,
the method comprising:
applying a first voltage V1 between one of the plurality of patch electrodes and the common electrode, and
determining whether the reflecting element is good or bad based on changes in a frame region that appears around a periphery of one of the plurality of patch electrodes in a top view when a voltage is applied between one of the plurality of patch electrodes and the common electrode.

2. The method according to claim 1, wherein the change in the frame region is a change in whether or not a frame region appears around the periphery of the plurality of patch electrodes in the top view when a voltage is applied between the plurality of patch electrodes and the common electrode.

3. The method according to claim 1, wherein whether or not a difference between a width L1 of a frame region when the first voltage V1 is applied and a reference width L1a of the frame region corresponding to the first voltage V1 is within ΔL1 is determined.

4. The method according to claim 3, further comprising,
applying a second voltage V2 different from the first voltage V1 between one of the plurality of patch electrodes and the common electrode, respectively, and
determining whether or not the width L1 of the frame region when the first voltage V1 is applied is different from a width L2 of the frame region when the second voltage V2 is applied.

5. The method according to claim 4, wherein an absolute value of the second voltage V2 is greater than an absolute value of the first voltage V1, and a reference width L2a of a frame region corresponding to the second voltage V2 is greater than the reference width L1a.

6. The method according to claim 3, further comprising,
applying a second voltage V2 different from the first voltage V1 between one of the plurality of patch electrodes and the common electrode, and
determining whether or not the difference between a width L2 of the frame region when the second voltage V2 is applied and a reference width L2a of a frame region corresponding to the second voltage V2 is within ΔL2.

7. The method according to claim 4,
applying a third voltage V3 between one of the plurality of patch electrodes and the common electrode, and
determining whether or not the width L2 is different from a width L3 of the frame region when the third voltage V3 is applied.

8. The method according to claim 7, wherein an absolute value of the third voltage V3 is greater than an absolute value of the second voltage V2, and a reference width L3a of a frame region corresponding to the third voltage V3 is greater than a reference width L2a of a frame region corresponding to the second voltage V2.

9. The method according to claim 6, further comprising,
applying a third voltage V3 between one of the plurality of patch electrodes and the common electrode, and
determining whether or not the difference between a width L3 of the frame region when the third voltage V3 is applied and a reference width L3a of a frame region corresponding to the third voltage V3 is within ΔL3.

10. The method according to claim 1, wherein the frame region surrounds the patch electrode in the top view, and the frame region is a top surface of a part of the liquid crystal layer.

11. The method according to claim 1, wherein a part of the liquid crystal layer sandwiches the liquid crystal layer between the patch electrode and the common electrode having a surface opposite to the patch electrode in a cross-sectional view.

12. The method according to claim 10, wherein a part of the liquid crystal layer is a part of the liquid crystal layer that is oriented by a diagonal electric field formed between the patch electrode and the common electrode.
